(19) United States
(12) Patent Application Publication
(10) Pub. No.: US 2018/0097128 A1
(43) Pub. Date: Apr. 5, 2018

(54) SOLAR CELL DEVICE AND METHOD FOR MANUFACTURING SAME

(71) Applicant: Material Concept, Inc., Sendai-shi, Miyagi (JP)

(72) Inventors: Junichi KOIKE, Sendai-shi, Miyagi (JP); Makoto WADA, Sendai-shi, Miyagi (JP); Yuji SUTOU, Sendai-shi, Miyagi (JP); Daisuke ANDO, Sendai-shi, Miyagi (JP)

(73) Assignee: Material Concept, Inc., Sendai-shi, Miyagi (JP)

(21) Appl. No.: 15/559,258

(22) PCT Filed: Mar. 7, 2016
(86) PCT No.: PCT/JP2016/056966

§ 371 Date: Sep. 18, 2017

(30) Foreign Application Priority Data
Mar. 20, 2015 (JP) 2015-058294

(51) Int. Cl. H01L 31/0224; H01L 31/05

(52) U.S. Cl. CPC H01L 31/022425; H01L 31/0512

(57) ABSTRACT

Provided is a solar cell device wherein: a Cu-containing metal layer exhibits good adhesion strength with respect to an Si substrate and a tab wire; and diffusion of Cu into the substrate and an Ag finger wiring line is suppressed. Provided is a solar cell device which comprises a silicon semiconductor substrate, a Cu-containing metal layer, an Ag-containing finger wiring line, and an interface layer containing an oxide or an organic compound. The Ag-containing finger wiring line is formed on the light receiving surface of the silicon semiconductor substrate; the interface layer is formed on the light receiving surface of the silicon semiconductor substrate; and the Cu-containing metal layer is formed on the interface layer and is arranged at a distance from the Ag-containing finger wiring line.

### TECHNICAL FIELD

The present invention relates to electrode wiring of a solar cell, and a surrounding structure thereof, and also relates to a structure of a Cu metal layer on a light-receiving surface and a process of forming the structure.

### BACKGROUND ART

In solar cells currently manufactured, Ag (silver) is commonly used as a wiring material for electrode wiring. However, the cost of Ag as a raw material, which is noble-metal material and expensive, accounts for 20% or more of the total cost of a solar cell. In order to reduce the cost of a solar cell, Cu (copper) has attracted much attention because the raw material cost of Cu is lower than that of Ag, and research and development have been actively conducted in order to adapt Cu as electrode wiring of a solar cell. Cu is a material with low resistance, and considered as a promising wiring material which can substitute Ag.

A silicon semiconductor substrate (Si substrate) of a solar cell constitutes a solar cell element including a diode, and enables a ray of light incident on the surface of the Si substrate to be converted into electricity to generate electric power. In order to take the resulting electric current out, two wiring structures: a finger wiring and a bus bar wiring are provided at the surface of an Si substrate of a solar cell as wiring for electrodes (which may also be referred as a finger electrode and a bus bar electrode, respectively). A finger wiring serves to collect an electric current generated at the Si substrate, and includes a large number of thin wires. A bus bar wiring serves to direct the electric current collected through the finger wiring to a tab wire. Then, the electric current is withdrawn to the outside though the tab wire (for example, see Patent Document 1).

A bus bar wiring serves to bundle a plurality of finger wirings to collect electricity, and is also designed to have a wiring width much wider than that of a finger wiring to maintain the adhesiveness with a tab wire and an Si substrate. Therefore, the area occupied by a bus bar wiring is large.

Patent Document 1: Japanese Unexamined Patent Application, Publication No. 2008-205137

Non-Patent Document 1: A. S. Grove, Physics and Technology of Semiconductor Devices, p40(1967)

### DISCLOSURE OF THE INVENTION

### Problems to be Solved by the Invention

Disadvantageously, the manufacturing cost of a solar cell device is high when expensive Ag is used as a material for a bus bar which has a large occupation area. Therefore, the manufacturing cost of a solar cell device may be able to substantially be reduced when less expensive Cu is substituted for expensive Ag. However, Cu and Si may undergo interdiffusion, and the diffusion rate of Cu in Si is very rapid (see Nonpatent Document 1). Therefore, when Cu is used for the conventional bus bar wiring, Cu atoms may easily enter into an Si semiconductor substrate. Cu entered into a substrate may form an acceptor level at an energy position deep in the band gap of silicon, resulting in a shortened carrier life time inside a diode. This may be responsible for deteriorated solar cell properties. Further, when Cu is used for a bus bar wiring, sufficient adhesiveness may not be obtained with an Si substrate or with an antireflection film (SiN, SiO₂, or the like) formed on an Si substrate. Disadvantageously, this may result in detachment of a Cu bus bar wiring from an Si substrate or an antireflection film.

Furthermore, when Cu is used for the conventional bus bar wiring, Cu may diffuse into an Ag finger wiring, through which Cu may diffuse into an Si substrate. Disadvantageously, this may deteriorate solar cell properties. Accordingly, an object of the present invention is to provide a solar cell device in which the above disadvantages can be overcome.

### Means for Solving the Problems

The present inventors found that provision of an interface layer including an oxide or an organic compound between an Si substrate and a Cu-containing metal layer can prevent Cu from diffusing into the Si substrate, and allow the Cu-containing metal layer to have a high adhesion strength with the Si substrate even when the Cu-containing metal layer is formed at a location where the conventional Ag bus bar wiring would be arranged. Further, the present investors found that the diffusion of Cu into an Si substrate through an Ag-containing finger wiring can be prevented when a Cu-containing metal layer is arranged so as to be separated from the Ag-containing finger wiring without making contact with each other. Moreover, the present investors found that a structure in which a Cu-containing metal layer, a tab wire, and an Si substrate have mutually good adhesion strength can be obtained when the Cu-containing metal layer is connected to the tab wire through a solder layer. Then the present invention has been completed. Specifically, the present invention can provide the following (1) to (10).

(1) A solar cell device having a silicon semiconductor substrate, Cu-containing metal layer, Ag-containing finger wiring, and an interface layer including an oxide or an organic compound, in which the Ag-containing finger wiring is layered on a light-receiving surface of the silicon semiconductor substrate, and the interface layer is layered on the light-receiving surface of the silicon semiconductor substrate, and the Cu-containing metal layer is layered on the interface layer, and arranged so as to be separated from the Ag-containing finger wiring.

(2) The solar cell device according to (1), in which an antireflection film is layered between the silicon semiconductor substrate and the interface layer.

(3) The solar cell device according to (1) or (2), in which the Cu-containing metal layer and the Ag-containing finger wiring are connected to a tab wire through a solder layer.

(4) The solar cell device according to any one of (1) to (3), including a structure in which the Ag-containing finger wiring includes a plurality of Ag-containing finger wirings, and the Cu-containing metal layer is arranged between the Ag-containing finger wirings, and the Ag-containing finger wirings are interrupted.

(5) The solar cell device according to any one of (1) to (4), including a structure in which the Cu-containing metal layer includes a plurality of Cu-containing metal layers, and the Ag-containing finger wiring is arranged between the Cu-containing metal layers, and the Cu-containing metal layers are interrupted.

(6) The solar cell device according to any one of (1) to (5), including a structure in which the Ag-containing finger wiring includes first Ag-containing finger wirings and a second Ag-containing finger wiring, and end portions of the first Ag-containing finger wirings are connected with the second Ag-containing finger wiring, and the solder layer is connected to the end portions.

(7) A method of manufacturing a solar cell device, the method including the steps of: forming an Ag-containing finger wiring on a light-receiving surface of a silicon semiconductor substrate; forming an interface layer including an oxide or an organic compound on the light-receiving surface; and forming a Cu-containing metal layer on the interface layer so as to be separated from the Ag-containing finger wiring.

(8) The method of manufacture according to (7), including the steps of: soldering the Cu-containing metal layer and the Ag-containing finger wiring; and soldering the Cu-containing metal layer and a tab wire.

(9) The method of manufacture according to (7) or (8), in which in the step of forming the Ag-containing finger wiring on the light-receiving surface of the silicon semiconductor substrate, an Ag paste is screen-printed on the light-receiving surface, and dried, and then subjected to fire-through firing; and in the step of forming the Cu-containing metal layer on the interface layer, a Cu paste is screen-printed on the interface layer, and dried, and then subjected to firing under an oxidizing atmosphere, and subjected to firing under a reducing atmosphere after the firing under the oxidizing atmosphere.

(10) The method of manufacture according to (7) or (8), in which in the step of forming the Ag-containing finger wiring on the light-receiving surface of the silicon semiconductor substrate and the step of forming the Cu-containing metal layer on the interface layer, an Ag paste is screen-printed on the light-receiving surface, and a paste including a Cu oxide is screen-printed on the interface layer, and the Ag paste and the paste including the Cu oxide are dried, and then subjected to fire-through firing, and subjected to firing under a reducing atmosphere after the fire-through firing.

### Effects of the Invention

The solar cell device according to the present invention has a structure in which a Cu-containing metal layer is formed on an interface layer including an oxide or an organic compound, and the Cu-containing metal layer is physically separated from an Ag-containing finger wiring. Therefore, direct entry of Cu atoms present in the Cu-containing metal layer into an Si substrate can be prevented, and a high adhesion strength can be obtained between the Cu-containing metal layer and the Si substrate through an interface layer. Further, entry of Cu atoms present in the Cu-containing metal layer into the Si substrate through the Ag-containing finger wiring can also be prevented. These features can prevent deterioration of the performance of a solar cell due to Cu atoms, and can maintain the reliability of the solar cell. Further, inexpensive Cu is substituted for Ag which has been conventionally used as a bus bar wiring material, and thus the manufacturing cost can be substantially reduced in accordance with the method of manufacturing a solar cell device according to the present invention.

### BRIEF DESCRIPTION OF THE DRAWINGS

FIG. 1 schematically shows an example of a wiring structure provided on a light-receiving surface of a solar cell device according to the present embodiment. FIG. 2 schematically shows various configurations of wiring structures provided at the sides of light-receiving surfaces of solar cell devices according to the present embodiment. FIG. 3 shows a schematic cross-sectional view of yet another example of a wiring structure on a light-receiving surface of a solar cell device according to the present embodiment. FIG. 4 schematically shows the steps of manufacturing the wiring structure of the solar cell device shown in FIG. 1. FIG. 5 schematically shows the steps of manufacturing the wiring structure of the solar cell device shown in FIG. 1. FIG. 6 shows an optical microscope image of a light-receiving surface of a solar cell corresponding to the configuration shown in FIG. 2(e). FIG. 7 shows the solar cell properties of a sample from FIG. 6. FIG. 8 schematically shows a wiring structure provided on a light-receiving surface of a solar cell device from Comparative Example. FIG. 9 shows an optical microscope image of a light-receiving surface of a solar cell corresponding to the configuration shown in FIG. 8. FIG. 10 shows the solar cell properties of a sample from FIG. 9.

### PREFERRED MODE FOR CARRYING OUT THE INVENTION

Below, embodiments of the present invention will be described, but the present invention shall not be limited to these embodiments. The solar cell device according to the present embodiment has a silicon semiconductor substrate, Cu-containing metal layer, Ag-containing finger wiring, and an interface layer including an oxide or an organic compound, in which the Ag-containing finger wiring is layered on a light-receiving surface of the silicon semiconductor substrate, and the interface layer is layered on the light-receiving surface of the silicon semiconductor substrate, and the Cu-containing metal layer is layered on the interface layer, and arranged so as to be separated from the Ag-containing finger wiring.

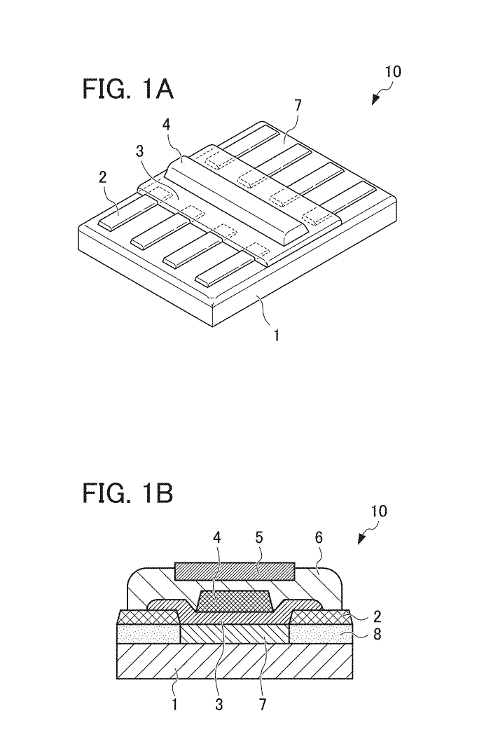

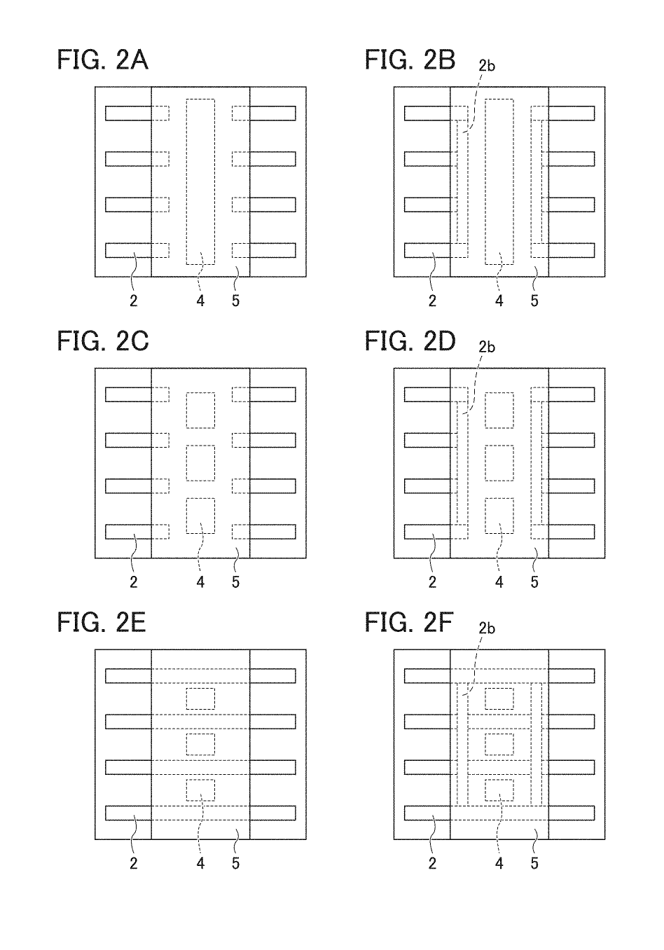

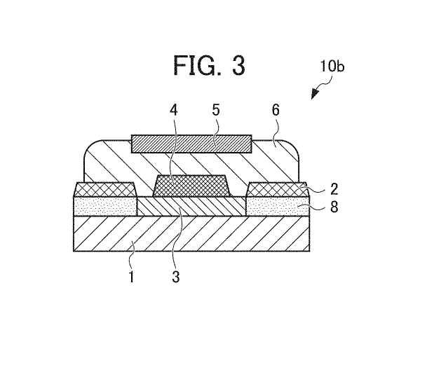

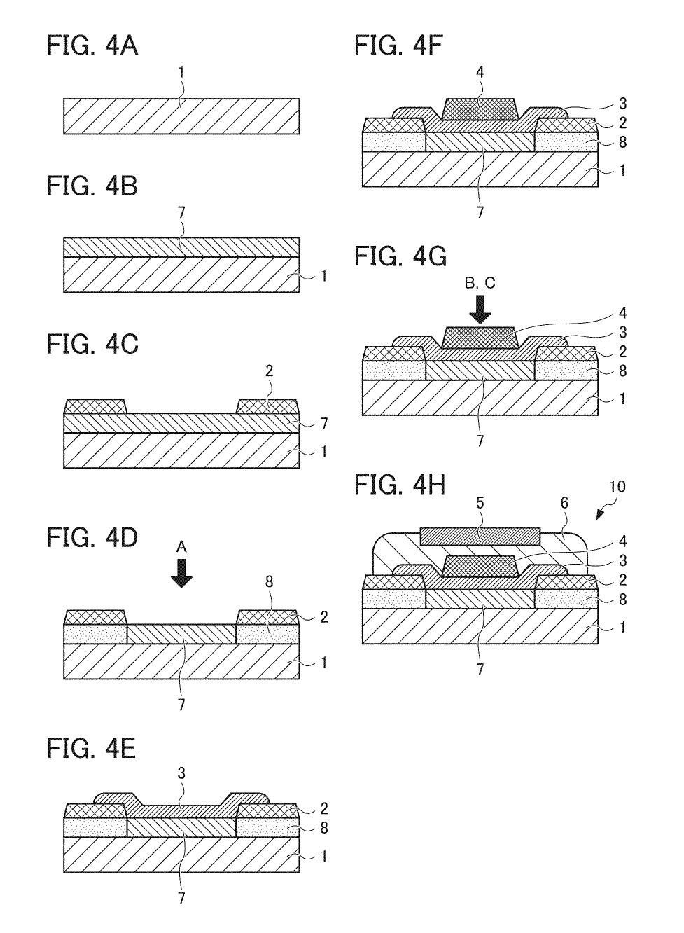

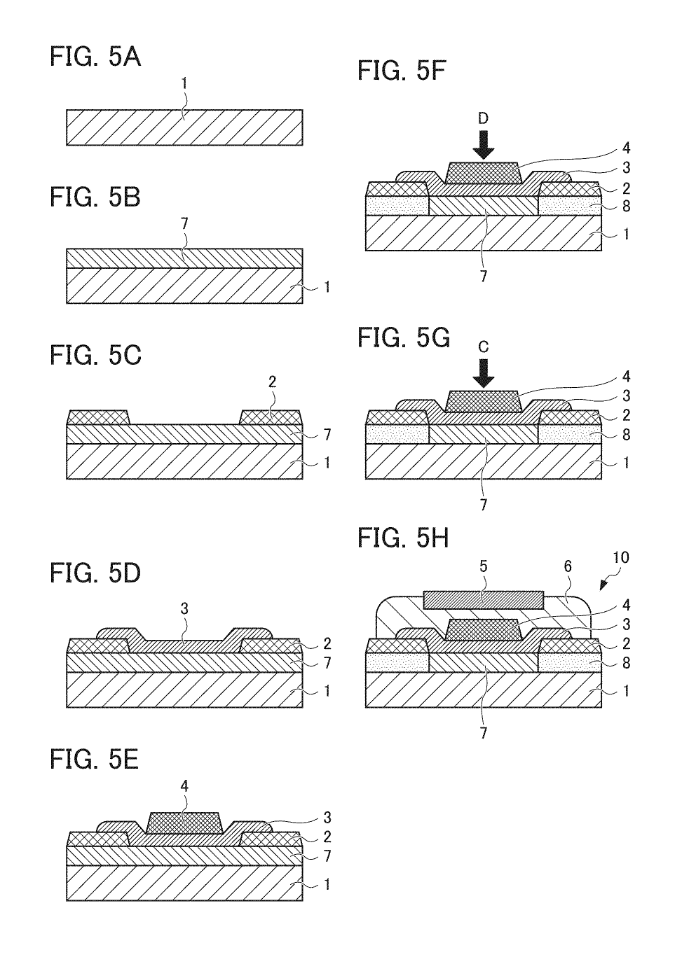

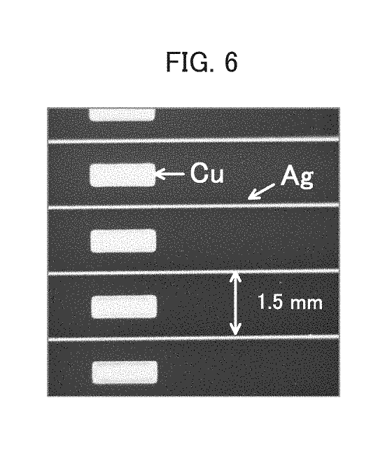

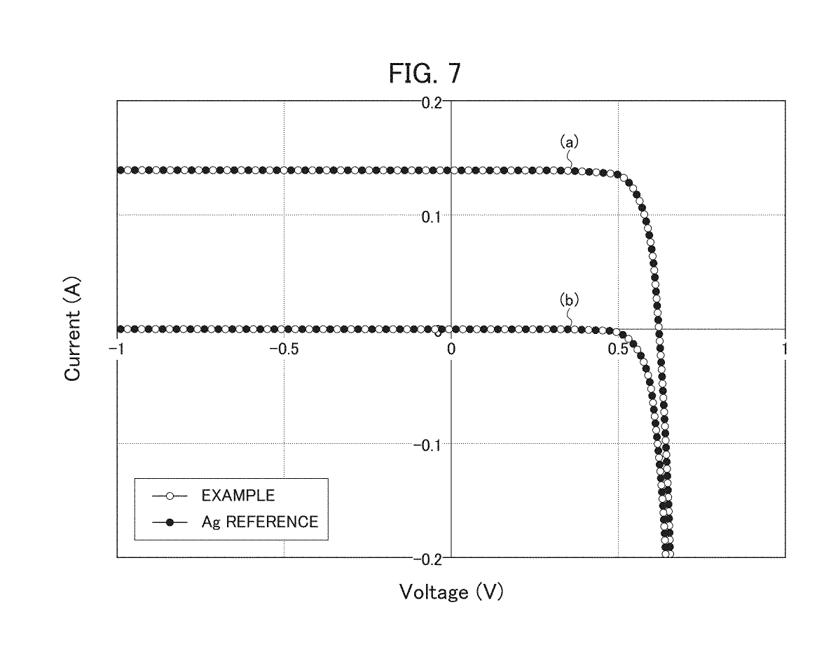

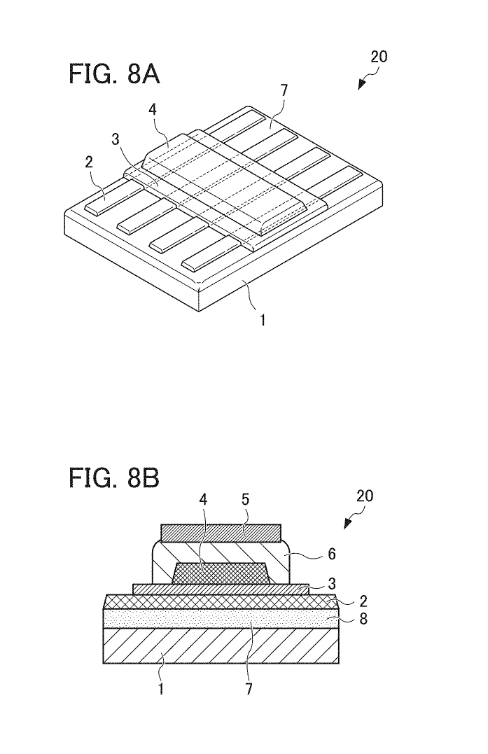

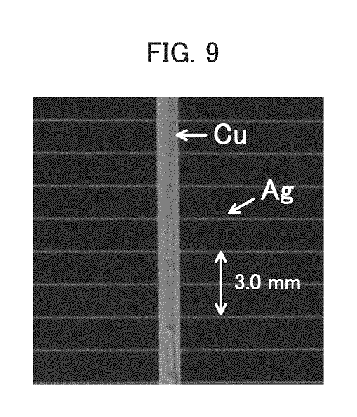

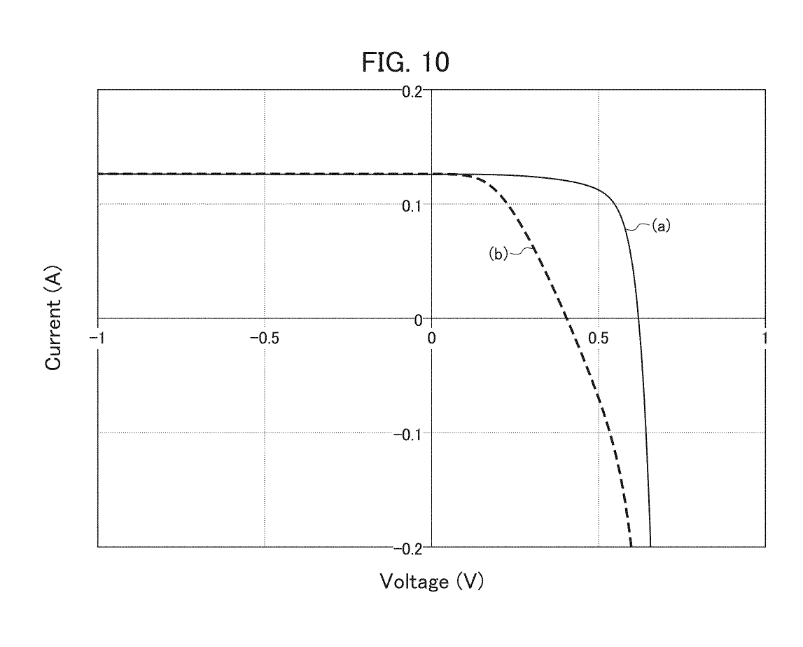

FIG. 1 schematically shows an example of a wiring structure on a light-receiving surface of a solar cell device according to the present embodiment. FIG. 1(a) shows a perspective view of a solar cell device. In a solar cell device 10, an antireflection film 7 is formed on a silicon semiconductor substrate (Si substrate) 1, and an Ag-containing finger wiring 2 and an interface layer 3 including an oxide or an organic compound are formed on the antireflection film 7. Further, a Cu-containing metal layer 4 is formed on the interface layer 3, and the Cu-containing metal layer 4 is arranged so as to be separated from the Ag-containing finger wiring 2. FIG. 1(b) is a cross-sectional view of a solar cell device, and a cross-sectional view of the solar cell device 10 further including a tab wire 5 and a solder layer 6 in the solar cell device 10 of FIG. 1(a). As shown in FIG. 1(b), the Cu-containing metal layer 4 is electrically connected to the tab wire 5 through the solder layer 6. The Cu-containing metal layer 4 is also electrically connected to the Ag-containing finger wiring 2 through the solder layer 6. The Cu-containing metal layer 4 is a metal layer made of a material including Cu as the main component. The Ag-containing finger wiring 2 is a finger wiring made of a material including Ag as the main component. The interface layer 3 is a layer arranged between the Si substrate 1 and the Cu-containing metal layer 4, and includes an oxide or an organic compound.

In the solar cell device 10 according to the present embodiment, the Cu-containing metal layer 4 and the Ag-containing finger wiring 2 are arranged so as to be separated without being overlapped with each other in the vertical direction (in the normal direction of the light-receiving surface plane of the Si substrate) and without making contact with each other. Cu and Ag are metals which have a range of solid solution at high temperature, and thus Cu tends to be diffused in Ag. Therefore, when the Cu-containing metal layer 4 makes contact with the Ag-containing finger wiring 2, Cu atoms may be diffused into the Si substrate 1 through the Ag-containing finger wiring 2. In contrast, in the solar cell device 10 according to the present embodiment, the Cu-containing metal layer 4 is arranged so as to be physically separated from the Ag-containing finger wiring 2, and does not make direct contact with the Ag-containing finger wiring 2. Therefore, diffusion of Cu atoms into the Si substrate 1 can be prevented. As described above, the solar cell device 10 according to the present embodiment can prevent deterioration of solar cell properties caused by diffusion of Cu, and can maintain good solar cell properties. Further, the manufacturing cost of a solar cell can be significantly reduced by substituting the conventional Ag bus bar wiring with the Cu-containing metal layer 4.

Further, the present embodiment preferably has a structure in which the Cu-containing metal layer 4 and the Ag-containing finger wiring 2 are electrically connected to the tab wire 5 arranged above the Cu-containing metal layer 4 through the solder layer 6 formed by soldering. Therefore, an electric current generated at the Si substrate is collected with the Ag-containing finger wiring 2, and then collected with the tab wire 5 through the solder layer 6 and the Cu-containing metal layer 4. This facilitates to take the electric current out from the solar cell device 10. Further, when the Ag-containing finger wiring 2 is directly contacted with the solder layer 6, the electric current can directly flow to the tab wire 5 from the Ag-containing finger wiring 2 through that contacted portion.

In the present embodiment, provision of the interface layer 3 can improve the adhesion strength of the Cu-containing metal layer 4 with the antireflection film 7 and the Si substrate 1. Moreover, the Cu-containing metal layer 4 has a high adhesion strength with the tab wire 5 through the solder layer 6. These adhesion strengths are comparable with those when the conventional Ag bus bar wiring is used.

As shown in FIG. 1, the interface layer 3 is preferably formed so that the width of the interface layer 3 in the longitudinal direction of the solar cell device 10 is wider than that of the Cu-containing metal layer 4. The interface layer 3 covers the bottom surface of the Cu-containing metal layer 4. This can prevent the contact of the Cu-containing metal layer 4 with the Si substrate, and thus prevent Cu atoms from entering into the Si substrate. The interface layer 3 may be formed so as to cover an end portion of the Ag-containing finger wiring 2, or may be formed so as not to cover the end portion of the Ag-containing finger wiring 2. At least a portion of the interface layer 3 may be present at a region between the Ag-containing finger wiring 2 and the Cu-containing metal layer 4 so that the Ag-containing finger wiring 2 is separated from the Cu-containing metal layer 4. Alternatively, the interface layer 3 may be formed over the entire light-receiving surface of the Si substrate 1. When the interface layer 3 is formed over the entire light-receiving surface of the Si substrate 1, the thickness of the antireflection film 7 is preferably reduced by the thickness of the interface layer 3.

Preferably, the tab wire 5 is layered over the Cu-containing metal layer 4 through the solder layer 6 with a high adhesion strength, and the Cu-containing metal layer 4 is layered over the antireflection film 7 and the Si substrate 1 through the interface layer 3 with a high adhesion strength. These features can provide the solar cell device 10 having the tab wire 5 with an excellent adhesion strength.

In a wiring structure where the conventional Ag bus bar wiring is used, an Ag fire through layer is formed by allowing Ag to enter into the antireflection layer under the Ag bus bar wiring to make electrical connection with the Si substrate. A region of the Si substrate directly under the Ag fire through layer serves as a site of carrier recombination. Therefore, the portion occupied by the Ag bus bar wiring does not contribute to accumulation of carrier (generation of electricity). In contrast, the Cu-containing metal layer 4 is formed on the antireflection film 7 in the solar cell device 10 according to the present embodiment. Therefore, the interface between the antireflection film 7 and the Si substrate 1 remains unchanged, and a site of carrier recombination is not formed. Consequently, the region of the Si substrate 1 located under the Cu-containing metal layer 4 also contributes to generation of electricity to increase the open circuit voltage of the solar cell. This can improve the efficiency of the solar cell, and thus represents a preferred aspect.

In the present embodiment, the antireflection film 7 may not be formed when the interface layer 3 has a high adhesion strength between the substrate 1 and the Cu-containing metal layer 4. The above configuration is preferred because the manufacturing process can be simplified. Further, the interface layer 3 preferably has a high adhesion strength with the Si substrate 1 and the Cu-containing metal layer 4, and provides barrier properties against diffusion of Cu into the Si substrate 1.

When the antireflection film 7 is formed, an Ag-containing fire through layer 8 can be formed under the Ag-containing finger wiring 2 as shown in FIG. 1(b) to secure electrical contact between the Si substrate 1 and the Ag-containing finger wiring 2. The Ag-containing fire through layer 8 is formed by allowing Ag to enter into the antireflection film 7 during high-temperature heat treatment for forming the Ag-containing finger wiring 2. An electric current generated at the Si substrate 1 flows to the Ag-containing finger wiring 2 through the Ag-containing fire through layer 8. Ag does not react with Si to form a reaction product, and diffusion rate of Ag in the Si substrate is very slow. Therefore, even if Ag diffuses through the antireflection film and reaches the Si substrate, it stays at the surface of the Si substrate, and thus does not cause deterioration of solar cell properties. However, in a case where the Cu-containing metal layer is in contact with the Ag finger wiring, Cu atoms reaches the Si substrate through the Ag finger wiring and the Ag fire through layer, and then diffuses into the Si substrate. This may cause deterioration of solar cell properties due to diffusion of Cu as described above. In contrast, the solar cell device 10 according to the present embodiment has a structure in which the Cu-containing metal layer 4 is arranged so as to be separated and separated from the Ag-containing finger wiring 2. Therefore, diffusion of Cu atoms into the Si substrate 1 through the Ag-containing finger wiring 2 and the Ag-containing fire through layer 8 can be prevented, which in turn can prevent deteriorated performance of the solar cell device 10.

The present embodiment preferably has a structure in which end portions of the Ag-containing finger wirings 2 are preferably connected to another Ag-containing finger wiring 2b, and the solder layer 6 is connected to these end portions.

FIG. 2 schematically shows the wiring structures of solar cell devices according to the present embodiment as seen from the above, and shows various positional relationships of the Ag-containing finger wiring 2, the Cu-containing metal layer 4, and the tab wire 5. FIG. 2(a) shows a wiring pattern example 1 shown in FIG. 1. A continuous stretch of the Cu-containing metal layer 4 having a rectangular parallelepiped shape is disposed between groups each including a plurality of Ag-containing finger wirings 2, the Ag-containing finger wirings 2 being arranged in a comb-like manner in each group. This provides a configuration in which the multiple Ag-containing finger wirings 2 are interrupted by the Cu-containing metal layer 4.

FIG. 2(b) shows a wiring pattern example 2, which is a modified version of the wiring pattern example 1. As shown in FIG. 2(b), end portions of a plurality of Ag-containing finger wirings 2 may be configured so as to be connected with another Ag-containing finger wiring 2b. The Ag-containing finger wirings 2 connected at their end portions are bonded with the tab wire 5 through the solder layer 6. An area where the tab wire 5 is soldered is increased when the end portions of the Ag-containing finger wirings 2 are connected as compared with a case where they are not connected. The increased area can enhance adhesion strength, and in addition, can reduce contact resistance to enable a larger electric current to be withdrawn, which in turn contributes to improvement in the reliability and manufacturing yield of the solar cell device 10.

In the solar cell device 10 according to the present embodiment, a plurality of Cu-containing metal layers 4 may be provided to have an interrupted structure, and preferably formed in an interrupted manner between a pluralities of Ag-containing finger wirings 2.

FIGS. 2(c) and 2(d) show wiring pattern examples 3 and 4, which are modified versions. The adhesion strength between the Si substrate 1 and the tab wire 5 is sufficiently assured by virtue of the adhesion strength mutually enhanced among the interface layer 3, the tab wire 5, and the Cu-containing metal layer 4. Therefore, a plurality of Cu-containing metal layers 4 may be provided in an interrupted manner, and arranged between groups of a plurality of Ag-containing finger wirings 2 arranged in a comb-like manner as shown in FIGS. 2(c) and 2(d). Even when the Cu-containing metal layers 4 are arranged in an interrupted manner, an electric current generated at the Si substrate 1 can flow to the tab wire 5 from the Ag-containing finger wiring 2 through the solder layer 6, and then can be withdrawn to the outside of the solar cell device 10. The wiring structure as described above can reduce the amount of a Cu paste used when forming the Cu-containing metal layers 4, leading to reduction of the manufacturing cost of a solar cell device.

FIGS. 2(e) and 2(f) shows wiring pattern examples 5 and 6 as modified versions. The Cu-containing metal layers 4 in an interrupted configuration may be arranged between continuous stretches of Ag-containing finger wirings 2. In the wiring structure as described above, a portion of the Ag-containing finger wiring 2 as a collector electrode which makes contact with the tab wire 5 is increased, enabling the generated electric power to be efficiently collected.

FIG. 3 shows a schematic cross-sectional view of yet another example of a wiring structure of the solar cell device according to the present embodiment. Shown is a solar cell device 10b having an Si substrate 1 and Ag-containing finger wirings 2 provided on the light-receiving surface of the Si substrate 1 through an Ag-containing fire through layer 8, in which a Cu-containing metal layer 4 arranged between the Ag-containing finger wirings 2 so as to be separated from the Ag-containing finger wirings 2, and an interface layer 3 is formed directly under the Cu-containing metal layer 4, and the Ag-containing finger wirings 2 and the Cu-containing metal layer 4 are connected to a tab wire 5 through a solder layer 6. In the configuration shown in FIG. 3, the interface layer 3 is arranged at a place where the antireflection film 7 in the configuration shown FIG. 1(b) is removed, and makes direct contact with the Si substrate 1. Therefore, the interface layer 3 provided between the Cu-containing metal layer 4 and the Si substrate 1 prevents diffusion of Cu atoms, and further serves to secure the adhesion strength among the Cu-containing metal layer 4, the interface layer 3, and the Si substrate 1. According to the configuration of the solar cell device 10b in FIG. 3, the tab wire 5 can be used to collect electricity not only from the Ag-containing finger wiring 2 but also from the Cu-containing metal layer 4, allowing electric power generated at the Si substrate 1 to be efficiently collected.

### (Method of Manufacture)

The method of manufacturing a solar cell device according to the present embodiment includes the steps of forming an Ag-containing finger wiring 2 on a light-receiving surface of an Si substrate 1 having a p-n junction and having a texture and an antireflection film formed thereon; forming a Cu-containing metal layer 4 at a place where a conventional bus bar wiring would be formed; and soldering the Cu-containing metal layer 4, the Ag-containing finger wiring 2, and a tab wire 5.

### (Method of Manufacturing 1)

The method of manufacturing a solar cell device according to the present embodiment preferably includes a step of forming the Ag-containing finger wiring 2 at the light-receiving surface of the Si substrate 1 by screen-printing an Ag paste, and drying at a temperature in a range of 150 to 300° C., and then performing fire-through firing at a temperature in a range of 750 to 900° C.; a step of applying a raw material solution for an interface layer to a place where the Cu-containing metal layer 4 will be formed; and a step of forming the Cu-containing metal layer 4 by screen-printing a Cu paste on the interface layer 3 applied, and drying at a temperature in a range of 150 to 300° C., and then performing oxidation firing at a temperature in a range of 300 to 500° C. under an oxygen atmosphere, and then further performing reduction firing at a temperature in a range of 300 to 500° C. under a reducing atmosphere of hydrogen, alcohol, ammonia, carbon monoxide, or the like.

### (Method of Manufacturing 2)

The method of manufacturing a solar cell device according to the present embodiment preferably includes the steps of forming the Ag-containing finger wiring 2 at the light-receiving surface of the Si substrate 1 and the Cu-containing metal layer 4 by screen-printing an Ag paste, and drying at a temperature in a range of 150 to 300° C., and applying a raw material solution for an interface layer to a place where the Cu-containing metal layer 4 will be formed, and screen-printing a Cu paste or a Cu oxide paste on the interface layer 3 applied, and drying at a temperature in a range of 150 to 300° C., and then performing fire-through firing at a temperature in a range of 700 to 900° C., and then further performing reduction firing at a temperature in a range of 300 to 500° C. under a reducing atmosphere of hydrogen, alcohol, ammonia, carbon monoxide, or the like.

The Cu oxide paste can be produced by mixing Cu₂O particles, a resin (cellulose), and an organic solvent (texanol). The Cu oxide paste may also contain CuO particles. When Cu₂O particles are mixed with CuO particles, the amount of CuO particles is 3 times or less of that of Cu₂O particles by the weight ratio.

### (Manufacturing Method Example 1)

FIG. 4 schematically shows the steps of manufacturing a wiring structure of a solar cell device according to the present embodiment. As shown in FIG. 4(a), the silicon semiconductor substrate (Si substrate) 1 is used as a substrate. An uneven texture architecture (not shown) may be formed on a surface of the light-receiving side of the Si substrate 1.

### (Formation of Antireflection Film)

As shown in FIG. 4(b), the antireflection film 7 is preferably formed on the Si substrate 1 in order to improve the conversion efficiency of the cell. The antireflection film 7 includes an insulating layer of SiN, SiO₂ or the like. The antireflection film 7 can be formed by the chemical vapor deposition (CVD) method. The thermal CVD method, the plasma CVD method, the atomic layer deposition method (ALD method), and the like can be used. The antireflection film 7 preferably has a thicknesses of about 30 nm to 100 nm.

### (Formation of Ag-Containing Finger Wiring)

Next, the Ag-containing finger wirings 2 are formed on the antireflection film 7 as shown in FIGS. 4(c) and 4(d). As a raw material, an Ag paste may be used in which an Ag powder is mixed with a glass frit, a resin component, and a solvent. The glass frit is added to assure electric ohmic contact and adhesion strength between the Ag-containing finger wiring 2 and the Si substrate 1. This can be achieved by melting a glass component and an antireflection-film component during a fire-through firing step, allowing Ag to diffuse into a molten region and reach the surface of the Si substrate. A silver paste is printed on the antireflection film 7 by the screen-printing method to form a predetermined wiring pattern, and then can be dried at about 150° C. to 300° C. to remove a highly volatile solvent (FIG. 4(c)).

Subsequently, the Ag paste printed as described above is fired for about several seconds to 10 and several seconds at 750 to 900° C. by an air firing A to form the Ag-containing finger wiring 2 (FIG. 4(d)). Further, in the above firing process, Ag penetrates through the antireflection film 7 to form an Ag-containing fire through layer 8 where Ag makes contact with the surface of the Si substrate 1.

### (Formation of Oxide Interface Layer)

Next, an oxide interface layer 3 as an interface layer containing an oxide is formed as shown in FIG. 4(e). For example, the deposition may be performed by the wet application method. When the wet application method is used, a metal organic compound, a metal chloride, or the like containing a predetermined component is mixed with a solvent to produce an application liquid as a raw material solution. A metal organic compound or metal chloride containing at least one of Mn, Ti, Mo, and W is preferably used. In particular, those containing Mn are more preferably used. Specifically, a solution in which manganese acetate is dissolved in alcohol and others may be used.

As a method to apply a raw material solution for the oxide interface layer 3, the slit coating, roller coating, ink-jet coating, spin coating, dip coating, spray coating methods, and the like can be used.

The raw material solution is applied on the antireflection film 7 formed on the Si substrate 1, and then drying treatment is performed at about 100° C. to 300° C. to evaporate and remove the solvent. Then, heat treatment may be performed at about 300° C. to 600° C. in order to form an oxide. When the temperature during the heat treatment is low, a carbon component from the raw material solution applied as described above may remain to reduce the adhesiveness with the Cu-containing metal layer 4. The heat treatment time is preferably about 1 minute to 30 minutes. The atmosphere during the heat treatment may be the air atmosphere or an oxygen atmosphere under reduced pressure.

As a method of depositing the oxide interface layer 3, publicly known deposition methods can also be used such as the chemical vapor deposition method and the sputtering method. Heat treatment is preferably performed at about 350° C. to 800° C. in order to form an oxide. The oxide interface layer 3 preferably includes at least one of Mn, Ti, Mo, and W. In particular, an oxide containing Mn is preferred.

The oxide interface layer 3 may be formed on the Si substrate 1, or may be formed so as to make contact with the Ag-containing finger wiring 2, or may be formed so as not to make contact with the Ag-containing finger wiring 2. Alternatively, it may be formed over the entire surface of the Si substrate 1.

### (Formation of Organic-Compound Interface Layer)

An organic-compound interface layer 3, which is an interface layer containing an organic compound, may be used instead of an oxide interface layer. Examples of the organic compound include epoxy resin-based adhesives, modified silicone-based adhesives, polyvinyl butyral resin adhesives belonging to polyvinyl alcohol, polybenzimidazole adhesives belonging to aromatic heterocycle polymer, polyimide-based adhesives, and the like. The adhesiveness as the interface layer 3 can be enhanced by heat curing each adhesive in accordance with a predetermined method.

### (Formation of Cu-Containing Metal Layer)

Next, the Cu-containing metal layer 4 is formed on the interface layer 3 as shown in FIGS. 4(f) and 4(g). A Cu paste prepared by mixing a Cu powder with a resin component and a solvent is used as a raw material. The Cu paste is printed on the oxide interface layer 3 by the screen printing method to form a predetermined wiring pattern, and then dried at a temperature of about 150° C. to 300° C. to evaporate and remove the solvent in the Cu paste (FIG. 4(f)). Subsequently, firing heat treatment (oxidation treatment B) as a first heat treatment is performed at a temperature of about 300° C. to 600° C. The heat treatment time is preferably about 1 minute to 15 minutes. The concentration of oxygen in the atmosphere is preferably 100 ppm or more, more preferably 500 to 3000 ppm. The resin component in the Cu paste is removed, and copper particles are oxidized to form copper oxide. The volume expansion upon oxidation is used to promote sintering (FIG. 4(g)).

Subsequently, reduction treatment C is performed as a second heat treatment at a temperature of about 300° C. to 600° C. under an atmosphere including carbon monoxide, alcohol, ammonia, formic acid, or hydrogen. The above atmosphere may further include oxygen. Addition of oxygen can reduce the reduction reaction of Cu, and thus can allow the reduction state of Cu to be controlled. The heat treatment time is preferably about 1 minute to 15 minutes. Copper oxide particles are reduced to copper particles to form the Cu-containing metal layer 4 (FIG. 4(g)).

### (Soldering to Tab Wire)

Next, as shown in FIG. 4(h), the Cu-containing metal layer 4 and the Ag-containing finger wiring 2 are soldered to the tab wire 5 to form solder connection. Before performing soldering, surface oxides, surface sulfides, or contaminant components on the Cu-containing metal layer 4 and the Ag-containing finger wiring 2 are removed, and a solder flux is applied in order to improve solder wettability. A solder flux may be applied by, for example, roller coating.

Soldering is performed after applying a solder flux. A solder material may be a lead solder or a lead-free solder, and common solder materials can be used. Soldering is preferably performed so that a solder material is bonded to both the Cu-containing metal layer 4 and the Ag-containing finger wiring 2. A solder material having a melting point of 400° C. or less is preferably used. A solder material having a melting temperature higher than 400° C. is not preferred because Cu atoms in the Cu-containing metal layer 4 may diffuse into the solder when performing soldering, and then diffuse into the Ag-containing finger wiring 2 through the solder layer 6.

As shown in FIG. 4(h), the tab wire 5 is electrically connected to both of the Ag-containing finger wiring 2 and the Cu-containing metal layer 4 through the solder layer 6 by performing soldering as described above. The tab wire 5 is preferably formed more widely than the Cu-containing metal layer 4, and preferably connected to the Cu-containing metal layer 4 at the location thereabove through the solder layer 6. A tab wire with a solder material pre-applied on the outside thereof may also be used. The tab wire 5 is preferably layered over the Cu-containing metal layer 4 through the solder layer 6 with a high adhesion strength. The adhesion strength is preferably such that the peel strength of the tab wire 5 per mm width is 2 N/mm or more. The Cu-containing metal layer 4 is preferably layered over the antireflection film 7 on the Si substrate 1 through the oxide interface layer 3 with a high adhesion strength. As a result, the solar cell device 10 can be formed in which the tab wire 5 and the Si substrate 1 are layered with a high adhesion strength. An electric current generated at the Si substrate 1 is collected through the Ag-containing finger wiring 2, and allowed to flow to the tab wire 5 through the solder layer 6 and the Cu-containing metal layer 4, and then withdrawn to the outside of the solar cell device 10.

### (Manufacturing Method Example 2)

FIG. 5 schematically shows the steps of manufacturing a wiring structure of the solar cell device according to the present embodiment. Another aspect of forming the Cu-containing metal layer 4 is shown in FIG. 5 which is different from the above manufacturing method example 1 (FIG. 4).

An Ag paste for forming the Ag-containing finger wiring 2 is printed on the antireflection film 7 as shown in FIGS. 5(a) to 5(c), and drying treatment is then performed at this point.

Subsequently, the interface layer 3 is formed as shown in FIG. 5(d). A raw material solution for the interface layer is applied according to a predetermined pattern, and heat treatment is then performed to form an oxide interface layer 3. The heating temperature at that time is preferably, for example, 300 to 500° C. such that firing of the Ag paste already printed is not effected.

Subsequently, a Cu paste for forming the Cu-containing metal layer 4 is printed on the interface layer 3 as shown in FIG. 5(e), and drying treatment can be then performed at this point.

Then, as shown in FIG. 5(f), firing treatment is performed to form the Cu-containing metal layer 4 and the Ag-containing finger wiring 2 at the same time. The above treatment, which is designated as the simultaneous firing treatment D, is preferably performed at 750° C. to 900° C. for several seconds to 10 and several seconds by air firing, which is consistent with the firing conditions for forming the Ag-containing finger wiring 2. During the above treatment, Ag in the Ag-containing finger wiring 2 penetrates through the antireflection film 7, and makes contact with the surface of the Si substrate 1. Therefore, the Ag-containing fire through layer 8 is also formed at the same time. The above firing treatment corresponds to the first oxidation heat treatment step for the Cu-containing metal layer 4 in the manufacturing method example 1, and a structure including copper oxide is formed.

Subsequently, reduction heat treatment (reduction treatment C) for forming the Cu-containing metal layer 4 is performed as shown in FIG. 5(g). The above treatment corresponds to the second reduction heat treatment step for the Cu-containing metal layer 4 in the manufacturing method example 1, and is performed as in the manufacturing method example 1.

Finally, as shown in FIG. 5(h), a solder connection step of soldering the tab wire 5 to the Ag-containing finger wiring 2 and the Cu-containing metal layer 4 is performed to complete the solar cell device 10. The solder connection step may be performed as in the manufacturing method example 1. The number of heat treatment steps is decreased by one when firing of the Cu-containing metal layer 4 and the Ag-containing finger wiring 2 is performed simultaneously. This can reduce the manufacturing cost of a solar cell.

### EXAMPLES

Below, the present invention will be described in more detail with reference to Examples, but the present invention shall not be limited to descriptions of these.

### Example 1

A sample of the solar cell device having a wiring structure shown in FIGS. 1(b) and 2(e) was produced, and the properties thereof were evaluated. The sample was produced by the method shown in FIG. 4. The Si substrate 1 was a p-type monocrystalline silicon wafer. The dimension of the substrate was 20 mm×20 mm with a thickness of about 0.2 mm. A surface of the above Si substrate 1 was etched with an alkaline solution to form a pyramid-shaped uneven structure (texture). Then, phosphorus was allowed to diffuse to form an n-type emitter layer, which in turn led to formation of a p-n junction. A film of silicon nitride having a film thicknesses of 70 nm was deposited on the light-receiving surface of the Si substrate 1 having the texture by the Plasma CVD method to obtain the antireflection film 7.

After a standard silver (Ag) paste was screen-printed on the antireflection film 7, this sample was dried at 180° C. under the air atmosphere to evaporate and remove a highly volatile organic solvent component. The Ag-containing finger wirings 2 each having a thicknesses of about 15 μm were formed so as to be arranged with an interval of 1.5 mm. Subsequently, heat treatment was performed at 800° C. for 5 seconds under the air atmosphere. During the above heat treatment, a glass frit, which was a component of the Ag paste on the Si substrate 1, underwent a melt reaction with the antireflection film 7 present directly beneath thereof to allow Ag to penetrate through the antireflection film 7 to form the Ag-containing fire through layer 8. The above Ag-containing fire through layer 8 was formed to allow Ag to make contact with the surface of the Si substrate 1. The sample was cooled to room temperature, and then removed from the fire-through furnace.

Next, in order to form, on the above sample, the metal oxide interface layer 3 as an interface layer containing a metal oxide, a raw material liquid for the metal oxide interface layer 3 was applied to a region of the antireflection film 7 on which the Cu-containing metal layers 4 were to be formed. As the raw material liquid, used was a solution in which an organic manganese compound (manganese acetate) was mixed with an anhydrous alcohol. It was applied to have a width of 2.0 mm along the width direction of a region of the Cu-containing metal layers 4. The above sample was placed on a hot plate, and drying treatment was performed at 200° C. for 10 minutes under the air atmosphere, and firing treatment was further performed at 450° C. for 10 minutes. The sample was cooled to room temperature, and then removed from the hot plate. The metal oxide interface layer 3 was formed to have a width of 2.0 mm along the width direction of a region of the Cu-containing metal layers 4, and also formed on the Ag-containing finger wirings 2 arranged at the extending portions of the Cu-containing metal layers 4. The thickness of the metal oxide interface layer 3 was found to be about 25 nm when a cross section of the sample was observed under a transmission electron microscope.

Next, in order to form the Cu-containing metal layers 4 on the above sample, a Cu paste was screen-printed at a space between the Ag-containing finger wirings 2 on which the interface layer 3 had been formed. The above sample was subjected to oxidation heat treatment at 450° C. for 5 minutes under a nitrogen gas atmosphere containing 1000 ppm of oxygen, and then subjected to reduction heat treatment at 475° C. for 5 minutes under a nitrogen gas atmosphere containing an ethanol gas. The sample was cooled to room temperature, and then removed from the oxidation heat treatment furnace. A light microscope image of the sample obtained is shown in FIG. 6. The Cu-containing metal layers were each formed at a space between the continuous stretches of the Ag-containing finger wirings, and each had a thickness of about 18 μm, and lengths of the sides of the rectangular body of 0.5 mm and 1.5 mm, and were not in contact with the Ag finger wirings.

Next, in order to solder the tab wire 5 on the above sample, an acidic solution (solder flux) was applied to remove oxides formed on the surfaces of the Cu-containing metal layer 4 and the Ag-containing finger wirings 2. Subsequently, the tab wire 5 pre-covered with a lead-free soldering material of an Sn—Ag—Cu alloy was soldered. As the tab wire 5, used was a rectangular Cu wire with a width of 2 mm.

A sample of the resulting solar cell device was evaluated by measuring for the adhesiveness of the tab wire 5 and the output characteristics of the solar cell device 10 as described below.

### (Adhesion Strength of Tab Wire 5)

An end of the tab wire was overlapped to a jig of a tensile testing machine, and pulled in the direction perpendicular to the substrate in accordance with a method described in JIS (JIS Z0237) to measure a peel strength of the tab wire. The results from the tests performed on 10 substrates showed that the mean value of the peel strength was 2.6 N/mm with a standard deviation error of ±0.4 N/mm.

### (Output Characteristics of Solar Cell Device)

The output characteristics of the solar cell device were measured in accordance with a method described in JIS (JIS C8913) using a solar simulator.

The results from measurements of the output characteristics of the solar cell device are shown in FIG. 7. In FIG. 7, (a) light-induced current represents a value of electric current when illuminated, and (b) dark current represents a value of electric current when not illuminated. The conversion efficiency of the sample produced was 18.72%. For comparison, a solar cell device having the same wiring structure as the sample produced in the present Example except that the Cu-containing metal layers 4 and the Ag-containing finger wirings 2 were both made of an Ag paste was produced. The output characteristics thereof are shown as the “Ag reference.” The conversion efficiency of the above sample was 18.68%. As clearly indicated in FIG. 7, the solar cell device formed using the configuration and method according to the present invention showed output characteristics comparable with those of the conventional solar cell device in which Ag is used for all of the wirings.

### Comparative Example 1

A sample of a solar cell device 20 having a wiring structure as schematically shown in FIG. 8 was produced as a Comparative Example with regard to the above Example 1, and the characteristics thereof were evaluated. The solar cell device 20 of Comparative Example 1 differs from the solar cell device 10 of Example 1 in that the Cu-containing metal layers 4 were not each arranged at a space between the Ag-containing finger wirings 2 in an interrupted manner, but rather a continuous stretch of the Cu-containing metal layer 4 was arranged over and perpendicular to continuous stretches of the Ag-containing finger wirings 2. Consequently, there existed portions where the Ag-containing finger wirings 2 and the Cu-containing metal layer 4 were overlapped one above the other, and contacted with each other. Except for this, the method of manufacturing the solar cell device 20 from Comparative Example 1 was the same as the method of manufacturing the solar cell device 10 from Example 1.

A light microscope image of the solar cell device 20 obtained is shown in FIG. 9. Further, the output characteristics of the solar cell device 20 are shown in FIG. 10.

FIG. 10 showed a slightly impaired squareness on the curve with regard to the output characteristics (a) after oxidation heat treatment. The output characteristics (b) after further performing additional reduction heat treatment showed a significantly decreased open circuit voltage, indicating that Cu was diffused into the Si substrate, and the conversion efficiency was significantly deteriorated. When a cross section of the sample was analyzed with a scanning electron microscope and X-ray energy dispersive spectrometer, a compound of Cu₃Si was found to be formed in the inside of the Si substrate directly under the Ag-containing finger wirings, showing that Cu was diffused in Si through the Ag finger wirings.

The Example according to the present invention showed good results with regard to the adhesiveness between the tab wire and the substrate, and the output characteristics of the solar cell. As described above, the solar cell device according to the present invention, which includes a Cu-containing metal layer provided at a place where the conventional Ag bus bar wiring would be arranged, can function as well as the conventional solar cell device, and can be manufactured at significantly reduced cost.

### EXPLANATION OF REFERENCE NUMERALS

1. Si substrate; 2. Ag-containing finger wiring; 3. Interface layer (oxide interface layer, organic-compound interface layer); 4. Cu-containing metal layer; 5. Tab wire; 6. Solder layer; 7. Antireflection film; 8. Ag-containing fire through layer; 10. Solar cell device.

1. A solar cell device having a silicon semiconductor substrate, Cu-containing metal layer, Ag-containing finger wiring, and an interface layer including an oxide or an organic compound, wherein
the Ag-containing finger wiring is located on a light-receiving surface of the silicon semiconductor substrate, and
the interface layer is located on the light-receiving surface of the silicon semiconductor substrate, and
the Cu-containing metal layer is located on the interface layer, and arranged so as to be separated from the Ag-containing finger wiring.

2. The solar cell device according to claim 1, wherein an antireflection film is layered between the silicon semiconductor substrate and the interface layer.

3. The solar cell device according to claim 1, wherein the Cu-containing metal layer and the Ag-containing finger wiring are connected to a tab wire through a solder layer.

4. The solar cell device according to claim 1, comprising a structure in which the Cu-containing metal layer is located between the plurality of Ag-containing finger wirings, and the Ag-containing finger wirings are interrupted.

5. The solar cell device according to claim 1, comprising a structure in which the Ag-containing finger wiring is located between the plurality of Cu-containing metal layers, and the Cu-containing metal layers are interrupted.

6. The solar cell device according to claim 1, comprising a structure in which the Ag-containing finger wiring comprises first Ag-containing finger wirings and a second Ag-containing finger wiring, and the end portions of the first Ag-containing finger wirings are connected to the second Ag-containing finger wiring, and the solder layer is connected to the end portions.

7. A method of manufacturing a solar cell device, the method comprising the steps of: forming an Ag-containing finger wiring on a light-receiving surface of a silicon semiconductor substrate;
forming an interface layer including an oxide or an organic compound on the light-receiving surface; and
forming a Cu-containing metal layer on the interface layer so as to be separated from the Ag-containing finger wiring.

8. The method of manufacturing according to claim 7, comprising the steps of:
soldering the Cu-containing metal layer and the Ag-containing finger wiring; and
soldering the Cu-containing metal layer and a tab wire.

9. The method of manufacturing according to claim 7, wherein in the step of forming the Ag-containing finger wiring on the light-receiving surface of the silicon semiconductor substrate, an Ag paste is screen-printed on the light-receiving surface, and dried, and then subjected to fire-through firing; and
in the step of forming the Cu-containing metal layer on the interface layer, a Cu paste is screen-printed on the interface layer, and dried, and then subjected to firing under an oxidizing atmosphere, followed by firing under a reducing atmosphere.

10. The method of manufacture according to claim 7, wherein in the step of forming the Ag-containing finger wiring on the light-receiving surface of the silicon semiconductor substrate and the step of forming the Cu-containing metal layer on the interface layer, an Ag paste is screen-printed on the light-receiving surface, and a paste including a Cu oxide is screen-printed on the interface layer, and the Ag paste and the paste including the Cu oxide are dried, and then subjected to fire-through firing, followed by firing under a reducing atmosphere.
